(19) United States
(12) Patent Application Publication
(10) Pub. No.: US 2015/0108621 A1
(43) Pub. Date: Apr. 23, 2015

(54) SHIELDED DEVICE PACKAGES AND RELATED FABRICATION METHODS

(71) Applicants: EDUARD J. PABST, MESA, AZ (US); ZHIWEI GONG, CHANDLER, AZ (US)

(72) Inventors: EDUARD J. PABST, MESA, AZ (US); ZHIWEI GONG, CHANDLER, AZ (US)

(21) Appl. No.: 14/056,644

(22) Filed: Oct. 17, 2013

(51) Int. Cl. H01L 23/552; H01L 23/492; H01L 23/31; H01L 21/56

(52) U.S. Cl. CPC H01L 23/552; H01L 21/565; H01L 23/492; H01L 23/3107
USPC 257/659; 438/124

(57) ABSTRACT

Shielded device packages and related fabrication methods are provided. An exemplary device package includes one or more electrical components, a molding compound overlying the one or more electrical components, a frame structure circumscribing the one or more electrical components, and a shielding structure overlying the frame structure and the one or more electrical components. The shielding structure contacts a first surface of the frame structure, at least a portion of the molding compound resides between the shielding structure and the one or more electrical components, and the first surface of the frame structure is aligned with a second surface of the portion of the molding compound.

### TECHNICAL FIELD

Embodiments of the subject matter described herein relate generally to electronic device packaging, and more particularly, to device packages with shielding from electromagnetic interference and related fabrication methods.

### BACKGROUND

Semiconductor devices are continually designed to be smaller, more complex and/or packaged more densely to thereby facilitate modern electronic devices that continually decrease in size and/or increase in complexity. For electronic devices that include multiple integrated circuits or multi-chip modules packaged within a relatively small area, minimizing electromagnetic interference (EMI) from external sources remains a concern. Many existing solutions for providing EMI shielding for device packages often undesirably increase size and/or costs or otherwise involve additional processing steps. For example, a cover may be provided over a semiconductor device package, which, in turn, increases the area footprint of the printed circuit board (PCB) or electronics substrate that the cover is mounted to and also requires additional fabrication steps be performed to align the cover with the semiconductor device package and affix the cover to the PCB or electronics substrate. Other approaches for integrating EMI shielding into multi-chip modules often require complex fabrication process steps that are difficult to implement and/or result in device packages that may be susceptible mechanical failures (e.g., delamination or the like).

### BRIEF DESCRIPTION OF THE DRAWINGS

The various embodiments will hereinafter be described in conjunction with the following drawing figures, which are not necessarily drawn to scale, wherein like numerals denote like elements, and wherein:

FIG. 1 depicts a perspective view of an exemplary device package in accordance with one or more embodiments of the invention;

FIG. 2 depicts a cross-sectional view of the device package of FIG. 1 when viewed along the line 2-2 in FIG. 1 in accordance with one or more embodiments of the invention;

FIGS. 3-10 illustrate, in cross section, exemplary methods for fabricating a shielded semiconductor device package in accordance with one embodiment of the invention;

FIG. 11 depicts a cross-sectional view of another exemplary device package in accordance with one or more embodiments of the invention;

FIG. 12 depicts a plan view of an exemplary metal layer suitable for use in a routing structure of a device package in accordance with one or more embodiments of the invention;

FIG. 13 depicts a cross-sectional view of another exemplary device package that includes wire bonding in accordance with one or more embodiments of the invention; and

FIG. 14 depicts a cross-sectional view of another exemplary device package that includes a flip chip electrical component in accordance with one or more embodiments of the invention.

### DETAILED DESCRIPTION

The following detailed description is merely illustrative in nature and is not intended to limit the embodiments of the subject matter or the application and uses of such embodiments. Any implementation described herein as exemplary is not necessarily to be construed as preferred or advantageous over other implementations. Additionally, there is no intention to be bound by any expressed or implied theory presented in the preceding technical field, background, or the following detailed description.

Embodiments of the subject matter described herein relate to device packages that incorporate shielding from electromagnetic interference (EMI). As described in greater detail below, one or more electrical components contained within a device package are circumscribed by a frame structure that is electrically connected to an overlying shielding structure that is bonded, joined, or otherwise coupled to the frame structure and spans the one or more electrical components. The frame structure provides lateral shielding from EMI while the shielding structure provides shielding from EMI in the direction orthogonal to the plane defined by the frame structure. In exemplary embodiments, the frame structure is embedded within a molding compound that overlies and surrounds or otherwise encapsulates the electrical components. In this regard, interior portions of the molding compound reside laterally between the frame structure and the electrical components and also between the shielding structure and the electrical components, while peripheral portions of the molding compound laterally circumscribe, surround, or otherwise encapsulate the frame structure.

In one or more embodiments, the shielded device package includes one or more semiconductor dies (or chips) that overlie a routing structure comprised of one or more redistribution metallization layers that provide vertical and/or lateral interconnections to/from the input and/or output interfaces (I/Os) of the semiconductor die(s) and connection structures (e.g., solder balls or the like) used to interface with the device package. In exemplary embodiments, the redistribution metallization layers are configured to provide an electrical connection between the frame structure and a ground reference voltage for the semiconductor die(s), so that the frame structure and the shielding structure conduct currents induced by EMI to ground. The frame structure is embedded within the molding compound, electrically grounded, and substantially planar in shape, and accordingly, the frame structure may alternatively be referred to herein as an embedded ground plane (EGP) frame.

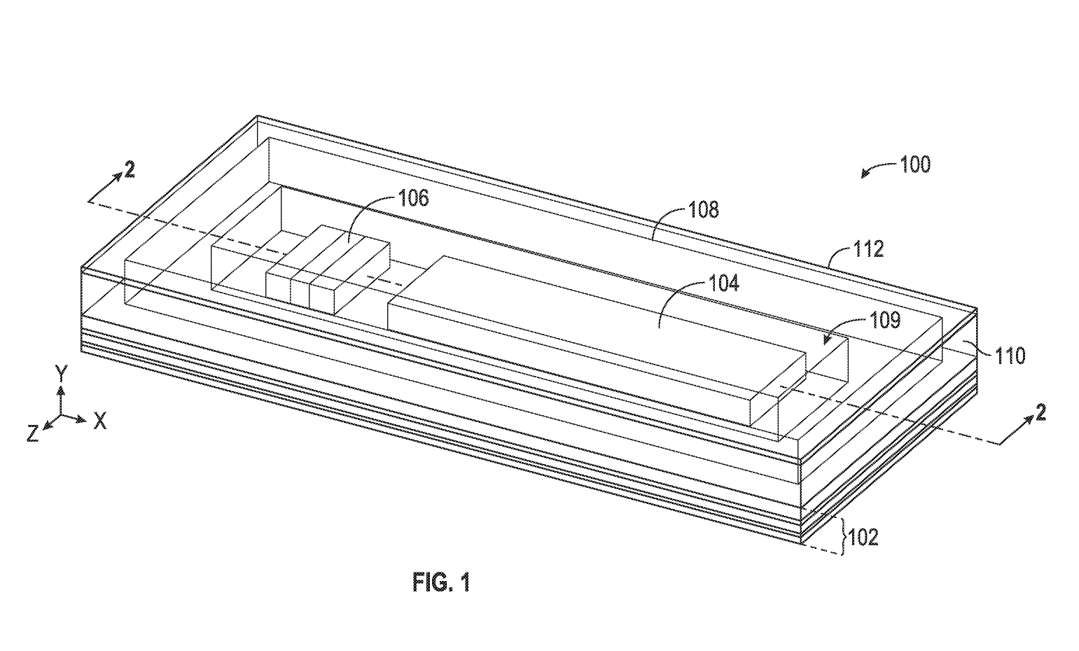

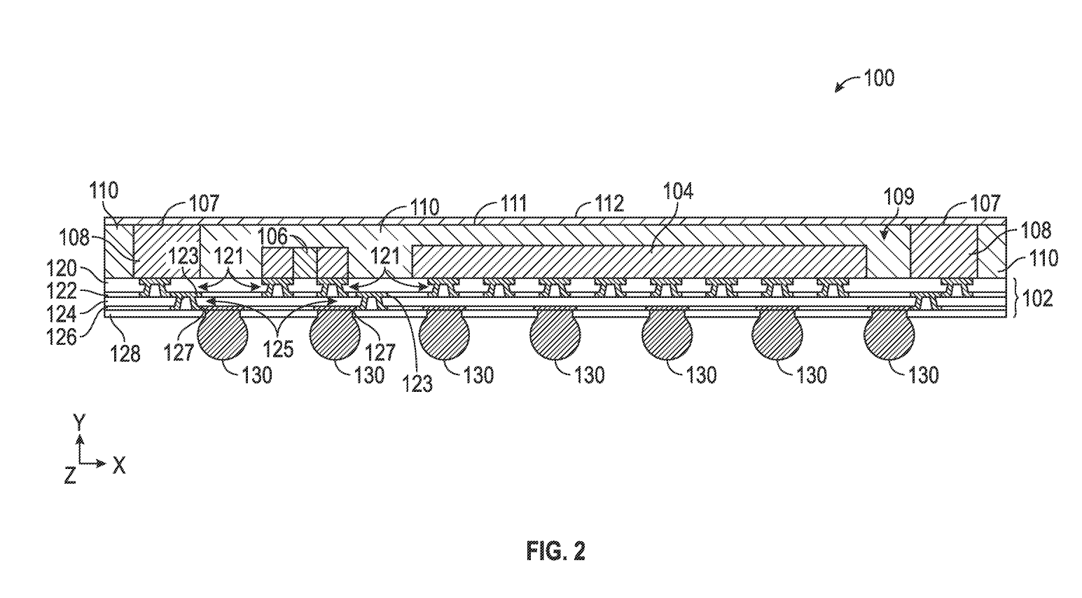

Turning now to FIGS. 1-2, in one or more exemplary embodiments, a semiconductor device package 100 includes one or more electrical components 104, 106 that are circumscribed or otherwise enclosed laterally by a frame structure 108 (e.g., in the xz reference plane). In exemplary embodiments, a molding compound 110 fills or otherwise occupies voids between the electrical components 104, 106 and/or frame structure 108, and thereby surrounds or otherwise encapsulates the electrical components 104, 106. Additionally, a routing structure 102 that functions as a substrate for the device package 100 is joined, mounted, affixed or otherwise mechanically coupled to the electrical components 104, 106 and the frame structure 108. As described in greater detail below, in exemplary embodiments, the routing structure 102 comprises one or more layers that are formed on the electrical components 104, 106, the frame structure 108, and the molding compound 110 and configured to provide the appropriate routing and/or electrical interconnections to/from the electrical components 104, 106 and the frame structure 108.

The semiconductor device package 100 includes a shielding structure 112 that is joined, mounted, affixed, adhered, bonded, or otherwise mechanically coupled to the frame structure 108 to enclose the electrical components 104, 106 in the dimension orthogonal to the plane defined by the frame structure 108 (e.g., in the y reference direction). In exemplary embodiments, the shielding structure 112 has a substantially planar shape and is aligned substantially parallel to the plane of the frame structure 108 and the routing structure 102, such that the routing structure 102, the frame structure 108, and the shielding structure 112 cooperatively surround or otherwise enclose the electrical components 104, 106 in three dimensions. In exemplary embodiments, the shielding structure 112 is electrically connected to the frame structure 108 to allow induced currents attributable to EMI to be conducted through the shielding structure 112 and the frame structure 108 to a reference potential, as described in greater detail below.

In exemplary embodiments, the electrical components 104, 106 include one or more semiconductor dies (or chips) that include one or more microelectronic semiconductor devices formed or otherwise fabricated thereon, such as, one or more processors, controllers, microprocessors, microcontrollers, memory elements, logic devices, transistors, resistors, capacitors, inductors, and/or the like. For example, at least a first electrical component 104 may be realized as a semiconductor die or another portion of a wafer of semiconductor material that includes one or more microelectronic semiconductor devices (e.g., transistors, memory cells, or the like) formed or otherwise fabricated thereon. Depending on the embodiment, another electrical component 106 in the device package 100 may be realized as another semiconductor die or a surface-mount electrical component. For purposes of explanation and without limitation, the first electrical component 104 may alternatively be referred to herein as a semiconductor die (or chip) and the second electrical component 106 may alternatively be referred to herein as a surface mount component. In this regard, it will be appreciated that the subject matter described herein is not limited to any particular type of electrical component contained within the device package or any particular combination of electrical components contained within the device package.

In exemplary embodiments, the frame structure 108 is realized as a substantially planar continuous structure that defines a hollow interior region 109 that the electrical components 104, 106 reside within. For example, as illustrated in FIGS. 1-2, the frame structure 108 is substantially aligned with the xz reference plane to laterally (or horizontally) circumscribe or otherwise enclose the electrical components 104, 106 in the x and z reference directions within the plane defined by the frame structure 108. As best illustrated in FIG. 2, the dimension of the frame structure 108 orthogonal to the xz reference plane in the y reference direction is greater than the maximum dimensions of the electrical components 104, 106 in the y reference direction, so that the frame structure 108 extends from the routing structure 102 in the y reference direction by a greater distance than the electrical components 104, 106. In other words, the height (or vertical or longitudinal dimension) of the frame structure 108 is greater than or equal to the height of the electrical components 104, 106 relative to the routing structure 102. In accordance with one or more embodiments, the height of the frame structure 108 is at least fifty microns greater than the height of the electrical components 104, 106. In an alternative embodiment, the height of the frame structure 108 is equal to the height of the electrical components 104, 106. Additionally, in exemplary embodiments, the inner perimeter of the frame structure 108 is greater than the outer perimeter of the footprint of the electrical components 104, 106 so that at least a portion of the molding compound 110 within the interior region 109 resides laterally between the frame structure 108 and the nearest electrical component(s) 104, 106.

The frame structure 108 is realized as a conductive material, such as a metal or alloy material (e.g., copper, copper alloy, alloy 42, nickel-iron alloy, or the like), to facilitate conducting induced currents attributable to EMI to a reference potential. As described in greater detail below, in exemplary embodiments, the frame structure 108 is electrically connected to a ground reference potential and is laterally enclosed or otherwise embedded within the device package 100 by the molding compound 110. In other words, peripheral portions of the molding compound 110 outside of the interior region 109 laterally circumscribe or otherwise enclose the frame structure 108. Accordingly, for purposes of explanation but without limitation, the frame structure 108 may alternatively be referred to herein as an EGP frame.

The molding compound 110 generally represents one or more dielectric encapsulant materials that encapsulate the electrical components 104, 106 and the frame structure 108. In this regard, the molding compound 110 fills any spaces between the electrical components 104, 106 and/or the frame structure 108 within the interior region 109 along with any spaces about the outer periphery of the frame structure 108 to protect the electrical components 104, 106 and the frame structure 108 from environmental elements (e.g., moisture, contamination, corrosion, and the like) and/or mechanical shock. The molding compound 110 may be formed by applying, injecting or otherwise forming any suitable encapsulant on or overlying the electrical components 104, 106 and the frame structure 108. For example, the molding compound 110 may be realized as a thermosetting epoxy molding compound formed overlying the electrical components 104, 106 and the frame structure 108 via printing, compression molding, or another molding technique. As described in greater detail below in the context of FIG. 6, in exemplary embodiments, the upper surface 111 of the molding compound 110 is substantially planar and substantially aligned with the upper surface 107 of the frame structure 108.

Still referring to FIGS. 1-2, in exemplary embodiments, the shielding structure 112 is realized as a substantially planar plate-like structure that is joined, mounted, affixed, adhered, bonded, formed on or otherwise mechanically coupled to the frame structure 108 and encloses the electrical components 104, 106 in the y reference direction orthogonal to the plane of the frame structure 108. In this regard, in embodiments where the vertical dimension (e.g., in the y reference direction) of the frame structure 108 is greater than the vertical dimension of the electrical components 104, 106, at least a portion of the molding compound 110 overlying the electrical components 104, 106 resides vertically between the shielding structure 112 and the electrical components 104, 106. In this regard, the lower surface of the shielding structure 112 is planar and abuts the planar surfaces 107, 111 of the frame structure 108 and the portion of the molding compound 110 overlying the electrical components 104, 106. The shielding structure 112 is realized as a conductive material, such as a metal material (e.g., copper, nickel, titanium tungsten, gold, or the like) to facilitate conducting induced currents attributable to EMI to a reference potential. In exemplary embodiments, the shielding structure 112 abuts or otherwise contacts the upper surface 107 of the frame structure 108, either directly or indirectly via a conductive adhesive material (e.g., solder or the like). Thus, the shielding structure 112 is electrically connected to the EGP frame 108, which, in turn, conducts currents induced in the shielding structure 112 by EMI vertically (e.g., in the y reference direction) to the ground reference potential.

As described in greater detail below in the context of FIG. 8, in exemplary embodiments, the routing structure 102 is realized as a plurality of redistribution metallization layers 120, 122, 124, 126, 128, such as, for example, alternating dielectric layers 120, 124, 128 and metal layers 122, 126. The first dielectric layer 120 is realized as a layer of dielectric material that is formed on or otherwise mechanically coupled to the electrical components 104, 106, the frame structure 108, and the molding compound 110. The first dielectric layer 120 includes a plurality of conductive vias 121 within the dielectric material that are aligned with the frame structure 108 and the I/O interfaces, pads, pins, terminals, or other connection locations on the electrical components 104, 106 to provide electrical connections to the frame structure 108 and the I/Os of the electrical components 104, 106 vertically through the first dielectric layer 120. The first metal layer 122 includes a conductive metal material 123 formed on the first dielectric layer 120 that is patterned to provide desired lateral electrical interconnections among the I/Os of the electrical components 104, 106 and/or vertical electrical connections through the first metal layer 122 to conductive vias 125 in the second dielectric layer 124. The conductive vias 125 of the second dielectric layer 124 are aligned with respect to the conductive material 123 in the first metal layer 122 to provide desired vertical electrical interconnections between the first metal layer 122 and the conductive metal material 127 of the second metal layer 126, which is similarly patterned to provide desired lateral electrical interconnections among the I/Os of the electrical components 104, 106 and/or vertical electrical connections through the second metal layer 126.

In the illustrated embodiment of FIGS. 1-2, a third dielectric layer 128 is formed on the second metal layer 126. The dielectric material of the third dielectric layer 128 is patterned to expose I/O pad portions of the metal material 127 of the second metal layer 126, and conductive connection structures 130 are formed on the exposed portions of the second metal layer 126 to provide appropriate I/O interfaces for the semiconductor device package 100. For example, the conductive connection structures 130 may be realized as solder balls (or solder bumps) that are formed on the exposed portions of the second metal layer 126 to facilitate soldering, bonding, or otherwise mounting the semiconductor device package 100 to a printed circuit board (PCB) or another electronics substrate that is appropriately patterned to conduct or otherwise transmit electrical signals to/from the I/Os of the semiconductor device package 100 to external electrical components and/or systems.

In exemplary embodiments, the metal layers 122, 126 and the vias 121, 125 within the dielectric layers 120, 124 are cooperatively configured to electrically connect the frame structure 108 to the conductive connection structure(s) 130 that is configured to receive a ground reference voltage for the semiconductor device package 100. In this manner, the EGP frame 108 is electrically connected to the ground reference potential of the device package 100 via the routing structure 102, and the shielding structure 112 is electrically connected to the ground reference potential via the EGP frame 108. Accordingly, the shielding structure 112 and the EGP frame 108 cooperatively provide a grounded EMI shield that substantially encloses or otherwise surrounds the electrical components 104, 106 of the device package 100 in the xz reference plane and the positive y reference direction. Accordingly, the susceptibility of the electrical components 104, 106 to EMI emanating from external sources that are laterally adjacent to the semiconductor device package 100 and/or above the semiconductor device package 100 in the positive y reference direction is reduced.

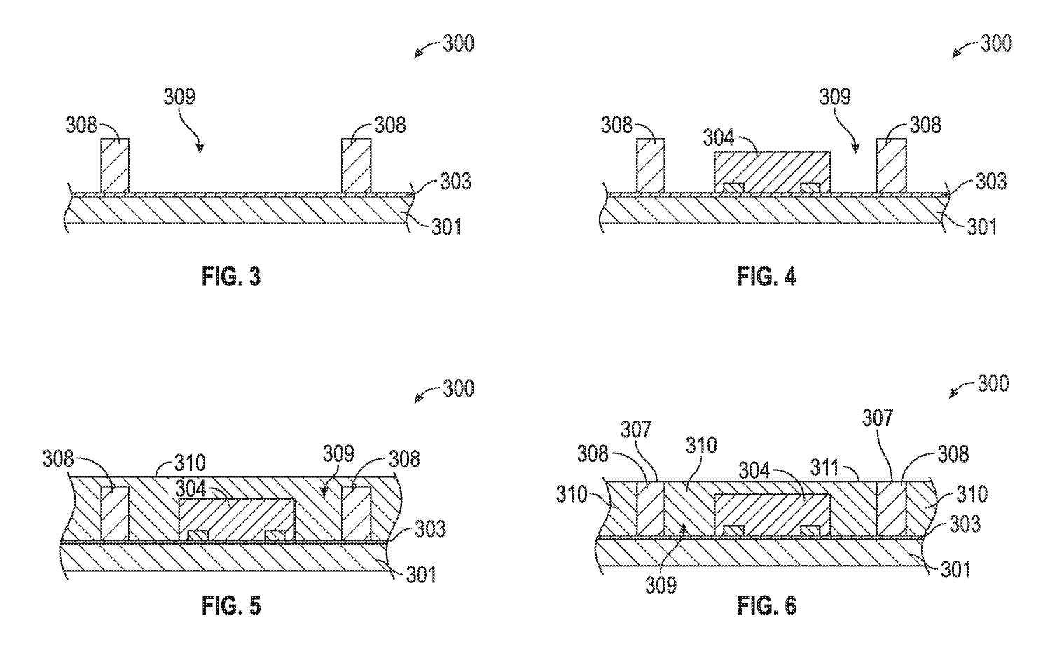

FIGS. 3-10 illustrate, in cross-section, exemplary methods for fabricating a shielded semiconductor device package 300, such as the device package 100 of FIG. 1. Various steps in the manufacture of semiconductor device packages are well known and so, in the interest of brevity, many conventional steps will only be mentioned briefly herein or will be omitted entirely without providing the well-known process details. Furthermore, although the subject matter may be illustrated and described herein in the context of a single semiconductor device package 300 for purposes of explanation, it should be understood that in practice, the semiconductor device package 300 is fabricated using fan-out wafer level packaging (FO-WLP) techniques to concurrently fabricate multiple instances of the semiconductor device package 300, for example, by performing wafer reconstruction using a carrier to provide multiple instances of the electrical components to be contained within the semiconductor device packages across the carrier.

Referring to FIG. 3, in exemplary embodiments, the fabrication process begins by applying a detachably adhesive structure 303 on a carrier substrate 301 and providing a frame structure 308 on the adhesive structure 303, which couples, joins, or otherwise adheres the frame structure 308 to the carrier substrate 301. The carrier substrate 301 may be realized using any suitable substantially rigid material capable of providing physical support for the adhesive structure 303. The adhesive structure 303 may be realized using any suitable adhesive material that is capable of detachably adhering to other structures or components that physically contact the adhesive structure 303. For example, in accordance with one or more embodiments, the adhesive structure 303 is realized as a double-sided tape. Applying the adhesive structure 303 to the surface of the carrier substrate 301 results in the adhesive structure 303 adhering to the surface of the carrier substrate 301. The frame structure 308 is provided on or otherwise brought into contact with the adhesive structure 303, which results in the frame structure 308 being detachably adhered to the carrier substrate 301 via the adhesive structure 303. In exemplary embodiments, the frame structure 308 is realized as a conductive material having a height relative to the carrier substrate 301 and/or adhesive structure 303 that is greater than the maximum height of the electrical component(s) 304 to be contained within the semiconductor device package 300. In other words, the height of the frame structure 308 relative to the carrier substrate 301 and/or the adhesive structure 303 that is greater than the height of all of the electrical component(s) 304 (e.g., the height of the frame structure 308 is greater than the height of tallest of the electrical component(s) 304).

Referring to FIG. 4, in one or more embodiments, after detachably adhering the frame structure 308 to the carrier substrate 301, the fabrication process continues by detachably adhering the electrical component(s) 304 of the semiconductor device package 300 to the carrier substrate 301 via the adhesive structure 303. As described above, in one or more embodiments, the electrical component 304 is realized as a semiconductor die, wherein after the desired functional and/or logic circuitry are fabricated on a wafer of semiconductor material and diced to obtain the semiconductor die 304, the semiconductor die 304 is provided on or otherwise brought into contact with the adhesive structure 303 within the hollow interior region 309 defined by the frame structure 308, resulting in the semiconductor die 304 being detachably adhered to the carrier substrate 301 and circumscribed by the frame structure 308. In exemplary embodiments, the side of the semiconductor die 304 that includes the I/O interfaces for the circuitry fabricated on the semiconductor die 304 (e.g., the active side) is oriented downward and placed in contact with the adhesive structure 303 to facilitate subsequent formation of electrical connections to/from the I/O interfaces of the semiconductor die 304. As illustrated, the height of the electrical component(s) 304 relative to the carrier substrate 301 and/or adhesive structure 303 is less than or equal to the height of the frame structure 308.

Referring now to FIGS. 5-6, in exemplary embodiments, after detachably adhering the frame structure 308 and the electrical component(s) 304 to the carrier substrate 301, the fabrication process continues by applying or otherwise forming a molding compound 310 overlying the electrical component(s) 304 and removing any portions of the molding compound 310 overlying the frame structure 308. For example, in accordance with one or more embodiments, the molding compound 310 may be formed by injecting or otherwise applying one or more encapsulant materials (e.g., epoxy, resin, or the like) overlying the carrier substrate 301 to a height (or thickness) that is greater than or equal to the height of the frame structure 308 (e.g., an overfill or flush fill), thereby ensuring that the interior region 309 defined by the frame structure 308 is completely filled by the molding compound 310. In this manner, the molding compound 310 encloses or otherwise surrounds the exposed surfaces of the electrical component(s) 304 and fills any voided portions of the interior region 309 that may reside laterally between the frame structure 308 and the electrical component(s) 304. Depending on the embodiment, one or more fabrication process steps may be performed to cure or otherwise set the molding compound 310 in a substantially rigid state that provides structural support to and/or mechanical coupling amongst the electrical component(s) 304 and the frame structure 308 after the carrier substrate 301 is detached or otherwise removed. In this regard, after the molding compound 310 is applied and set, the combination of the electrical components 304, the frame structure 308, and the molding compound 310 effectively provides a reconstructed wafer that includes the electrical components 304 thereon.

Referring to FIG. 6, in the illustrated embodiment, after forming the molding compound 310 overlying the electrical component(s) 304, the fabrication process continues by removing portions of the molding compound 310 overlying the frame structure 308 to expose the upper surface 307 of the frame structure 308. In exemplary embodiments, portions of the molding compound 310 overlying the electrical component(s) 304 and the frame structure 308 are removed substantially uniformly across the carrier substrate 301 to provide a substantially planer upper surface 311 of the molding compound 310 that is substantially aligned with the upper surface 307 of the frame structure 308. For example, in one embodiment, a grinding process may be performed to uniformly grind the molding compound 310 to until reaching the desired thickness (or height) that results in the upper surface 307 of the frame structure 308 being exposed and the upper surface 311 of the molding compound 310 being laterally aligned with the upper surface 307 of the frame structure 308. In alternative embodiments, a planarization or polishing process (e.g., chemical-mechanical planarization or the like) may be performed to remove excess portions of the molding compound 310 overlying the frame structure 308 to expose the upper surface 307 of the frame structure 308 and achieve a substantially planar upper surface 311 aligned with the upper surface 307 of the frame structure 308. In this regard, the subject matter described herein is not limited to any particular manner of removing portions of the molding compound 310 to obtain an upper surface 311 laterally aligned with the upper surface 307 of the frame structure 308. When the height of the frame structure 308 is greater than the electrical component(s) 304, portions of the molding compound 310 remain intact overlying the electrical component(s) 304 after portions of the molding compound 310 overlying the frame structure 308 are removed. In an alternative embodiment, the molding compound 310 could be removed to the height of the electrical component(s) 304 to expose the back side of the electrical component(s) 304 aligned with the upper surface 311. Furthermore, in some embodiments, the molding compound 310 may be formed to the height of the frame structure 308 (e.g., by compression molding), in which case the process steps described here in the context of FIG. 6 may be omitted from the overall fabrication process.

Referring now to FIGS. 7-8, in exemplary embodiments, after forming a molding compound 310 that encapsulates or otherwise surrounds the electrical component(s) 304 and the frame structure 308, the fabrication process continues by removing or otherwise detaching the carrier substrate 301 from the reconstructed wafer to expose the backside of the electrical component(s) 304 and forming a routing structure 302 on the backside of the reconstructed wafer to provide the desired electrical interconnections to/from the electrical component(s) 304 of the semiconductor device package 300. In this regard, the electrical component(s) 304, the frame structure 308, and the molding compound 310 are collectively detached or otherwise removed from the adhesive structure 303 in unison to obtain the reconstructed wafer that is physically distinct or otherwise separate from the carrier substrate 301 and expose the active side of the electrical component(s) 304.

In the illustrated embodiment of FIG. 8, after the active side of the electrical component(s) 304 and the bottom surface of the frame structure 308 are exposed, the redistribution layers 320, 322, 324, 326, 328 for the routing structure 302 are fabricated on the active side of the reconstructed wafer. For example, the first dielectric layer 320 may be formed by depositing or otherwise forming a layer of dielectric material on the active side of the electrical component(s) 304 and the bottom surfaces of the frame structure 308 and the molding compound 310, forming openings or voids in the dielectric material aligned with the frame structure 308 and the I/Os of the electrical component(s) 304, and depositing or otherwise forming a conductive material in the voids to provide conductive vias in contact with the frame structure 308 and the I/Os of the electrical component(s) 304. Thereafter, the first metal layer 322 may be formed by depositing or otherwise forming a layer of dielectric material on the first dielectric layer 320, forming voids in the dielectric material that are aligned with the conductive vias in the first dielectric layer 320 and patterned to provide the desired routing amongst the I/Os of the electrical component(s) 304, and depositing or otherwise forming a conductive metal material in the voids to provide the desired lateral interconnections amongst the I/Os of the electrical component(s) 304 and the frame structure 308 within the first metal layer 320. In this regard, in some embodiments, the first metal layer 322 may be patterned to electrically connect the frame structure 308 with the I/O of a semiconductor die 304 that corresponds to the ground reference potential for the circuitry fabricated on the semiconductor die 304.

The additional dielectric and metal layers 324, 326 may be formed in a similar manner to provide additional vertical and/or lateral interconnections to/from the I/Os of the electrical component(s) 304 and/or the frame structure 308. In this regard, in some embodiments, in lieu of or in addition to patterning the first metal layer 322 to provide an electrical connection between the frame structure 308 and the I/O of a semiconductor die 304 that corresponds to the ground reference potential, the second metal layer 326 may be patterned to electrically connect the frame structure 308 with the I/O of the semiconductor die 304 that corresponds to the ground reference potential. After metal layers 322, 326 and dielectric layers 320, 324 are formed, an outer dielectric layer 328 is formed by depositing or otherwise forming a layer of a dielectric material, etching or otherwise removing portions of the dielectric material aligned with pad portions of the underlying metal layer 326 that correspond to subsequently formed conductive connection structures 330.

Referring now to FIG. 9, after forming the routing structure 302 on the backside of the reconstructed wafer, the fabrication process continues by forming a shielding structure 312 on the opposing side (e.g., the topside) of the reconstructed wafer. For example, in one or more embodiments, a contiguous layer of a conductive metal material, such as copper nickel, titanium tungsten, gold, or the like, may be formed on the upper surfaces 307, 311 of the frame structure 308 and the molding compound 310 by sputtering, physical vapor deposition (PVD), or another suitable deposition process. In this manner, the shielding structure 312 abuts or otherwise contacts the upper surface 307 of the frame structure 308, thereby establishing an electrical connection. In one or more embodiments, when PVD is performed to fabricate the shielding structure 312, the thickness of the shielding structure 312 may range from about 0.2 microns to about 1 micron. In another embodiment, when sputtering or another process is performed to fabricate the shielding structure 312, the thickness of the shielding structure 312 may range from about 1 micron to about 10 microns. To achieve relatively higher thicknesses, in some embodiments, a sputtering or deposition process may be performed to form a relatively thinner layer of conductive metal material followed by a plating process to increase the thickness of the conductive metal material to the desired thickness for the shielding structure 312. By virtue of the physical contact between the frame structure 308 and the shielding structure 312, the shielding structure 312 and the frame structure 308 are electrically connected to one another and also to the ground reference potential to facilitate conducting currents induced by EMI in the shielding structure 312 to ground. It should be noted that although the subject matter is described herein in the context of the routing structure 302 being fabricated prior to fabricating the shielding structure 312, in alternative embodiments, the shielding structure 312 may be fabricated prior to fabricating the routing structure 302.

Still referring to FIG. 9, in exemplary embodiments, after fabricating the shielding structure 312, the conductive connection structures 330 are formed on or otherwise in contact with the exposed pad portions of the metal layer 326 to provide the desired I/O interfaces for the resulting semiconductor device package 300. As described above, the underlying metal layers 322, 326 are patterned or otherwise configured so that the frame structure 308 is electrically connected to the particular connection structure 330 that corresponds to the ground reference potential for the device package 300.

Turning now to FIG. 10, fabrication of the device package 300 is completed by dicing, sawing, or otherwise singulating the reconstructed wafer about the frame structure 308. In this regard, the scribe lines used to singulate the reconstructed wafer are offset from the frame structure 308 by a nonzero distance so that the resultant package 300 includes peripheral portions of molding compound 310 that laterally circumscribe or otherwise enclose the frame structure 308. The peripheral portions of the molding compound 310 prevent inadvertent lateral electrical connections to the frame structure 308 that could otherwise influence the electrical potential of the frame structure 308. After singulation, the connection structures 330 may be utilized to solder, mount, bond, join, affix, or otherwise adhere the device package 300 to a PCB or other electronics substrate configured to route or otherwise transmit the appropriate I/O and reference voltage signals for the electrical component(s) 304 to/from the device package 300. As described above, the ground reference voltage potential provided to the electrical component(s) 304 via the connection structure(s) 330 is also provided to the frame structure 308 and the shielding structure 312 via the metal layers 322, 326, so that the frame structure 308 and the shielding structure 312 provide a grounded EMI shield that encloses or otherwise surrounds the electrical component(s) 304 of the device package 300 above the routing structure 302.

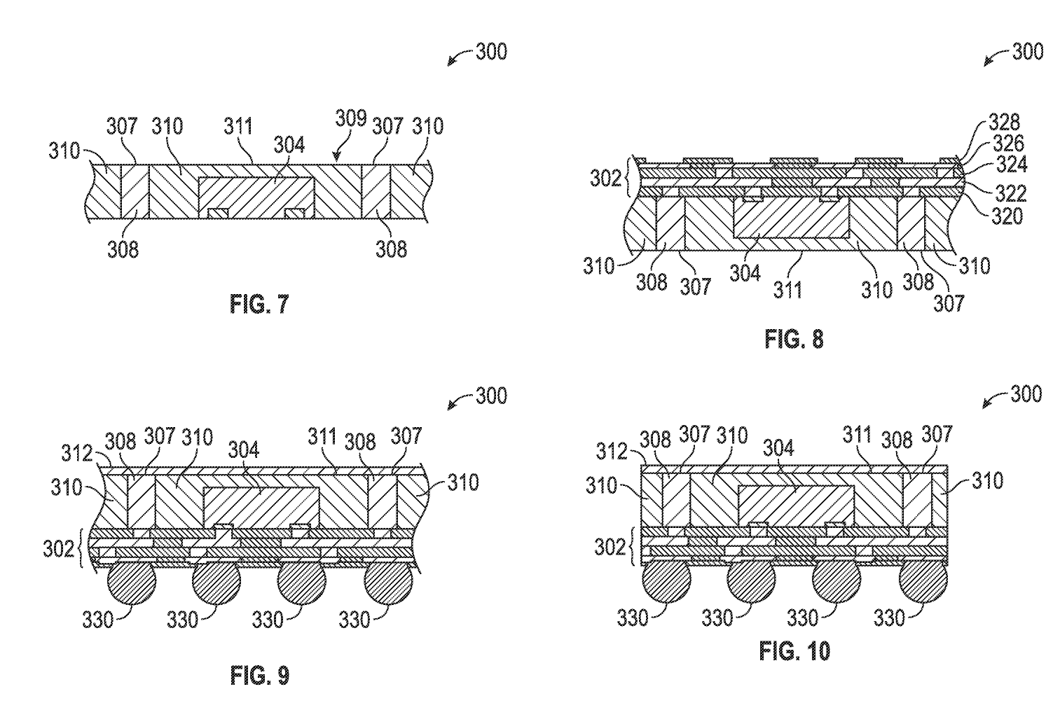

FIG. 11 depicts another embodiment of a shielded semiconductor device package 400 that includes a conductive shielding structure 412. In the embodiment of FIG. 11, the shielding structure 412 is realized as a conductive metal material that is formed into plate or another suitable planar structure that is bonded, joined, mounted, soldered, affixed or otherwise adhered to the upper surface 107 of the frame structure 108 and spans the interior region 109 defined by the frame structure 108. In this regard, in lieu of forming a conductive metal material on the topside of the reconstructed wafer as described above in the context of FIG. 9 (e.g., by deposition, sputtering, plating, or the like), the device package 400 of FIG. 11 is achieved by aligning the shielding structure 412 with the frame structure 108 and fixedly engaging the shielding structure 412 in electrical contact with the frame structure 108. For example, the shielding structure 412 may be realized as a copper plate that is soldered to the upper surface 107 of the frame structure 108 by performing a reflow soldering process. Alternatively, the shielding structure 412 may be bonded to the upper surface 107 of the frame structure 108, for example, by using a conductive epoxy. In this regard, depending on the embodiment, the shielding structure 412 may contact the frame structure 108 directly or indirectly via the conductive adhesive used to adhere the shielding structure 412 to the frame structure 108. It should be noted that depending on the process used to fixedly engage the shielding structure 412 in electrical contact with the frame structure 108, the interior portion of the shielding structure 412 that overlies the interior region 109 may or may not be joined or otherwise adhered to the underlying molding compound 110 within the interior region 109.

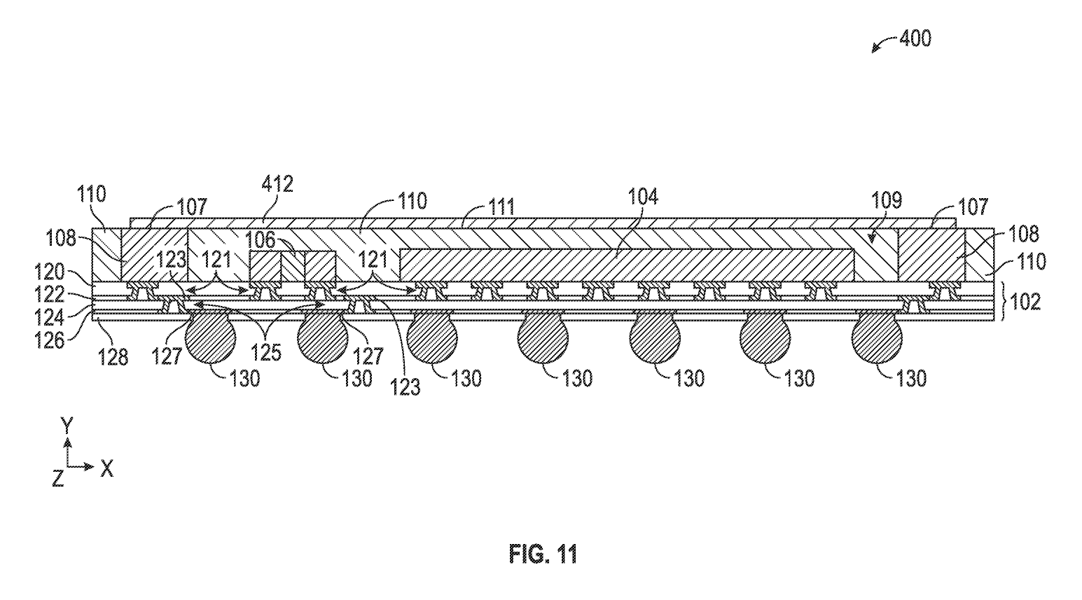

FIG. 12 depicts a plan view of a metal layer 500 suitable for use as a metal layer in the routing structure of a shielded semiconductor device package, such as, for example, a metal layer 122, 126 in the routing structure 102 or a metal layer 322, 326 in the routing structure 302. As illustrated, the metal layer 500 includes a first portion 552 of a conductive metal material that is patterned to provide a planar or plate-like lateral routing pattern that functions as a second shielding structure. Accordingly, the portion 552 of the metal layer 500 may alternatively be referred to herein as the second shielding structure or the lower shielding structure. In exemplary embodiments, the perimeter of the second shielding structure 552 corresponds to the perimeter of the frame structure 108, 308 and is substantially vertically aligned with the frame structure 108 (e.g., in the y reference direction) such that any conductive vias aligned with the frame structure 108 contact the second shielding structure 552. In this regard, the second shielding structure 552 is electrically connected to the frame structure 108, 308, such that the frame structure 108, 308, the upper shielding structure 112, 312, 412, and the lower shielding structure 552 all have substantially the same electrical potential. In this manner, the lower shielding structure 552, the upper shielding structure 112, 312, 412, and the frame structure 108, 308 substantially enclose the electrical components 104, 106, 304 in all directions (with the exception of the openings or voids 554 formed within the second shielding structure 552) to provide an effective three-dimensional EMI shield that is integrated within the semiconductor device package. Within the openings 554, portions 556 of the conductive metal material of the metal layer 500 are patterned to provide metal landings aligned with conductive vias in the adjacent dielectric layers above and below the metal layer 500 to provide vertical electrical connections through the metal layer 500 for the I/Os of the electrical components 104, 106, 304. For example, in an exemplary embodiment, the first metal layer 122 is realized as the metal layer 500, with the openings 554 and metal landings 556 being vertically aligned with conductive vias that are vertically aligned with the I/Os of the electrical components 104, 106 to provide a vertical electrical connection through the first metal layer 122 to the second metal layer 126 (and/or any additional metal layers), which is utilized to provide the desired lateral interconnections to/from the I/Os of the electrical components 104, 106.

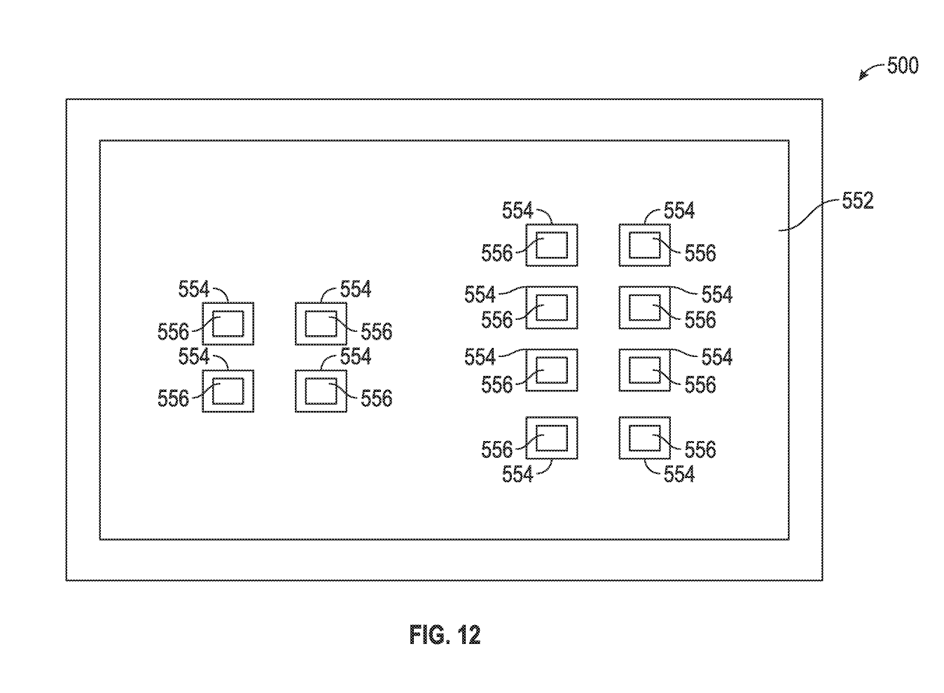

FIG. 13 depicts an alternative embodiment of a shielded semiconductor device package 600 that includes wire bonds 601 between I/Os on the topside of an electrical component 604, such as a semiconductor die, and bonding locations on an underlying routing structure 602. The bonding locations for the wire bonds 601 are located on the routing structure 602 within the interior region defined by the frame structure 608, and the molding compound 610 surrounds or otherwise encapsulates the wire bonds 601 and the electrical component 604. The overlying shielding structure 612 is electrically connected to the frame structure 608, which, in turn, is electrically connected to a particular connection structure 630 configured to receive a reference voltage via the routing structure 602. Additionally, the routing structure 602 is configured to electrically connect the wire bonds 601 to the particular connection structures 630 corresponding to those I/Os of the electrical component 604.

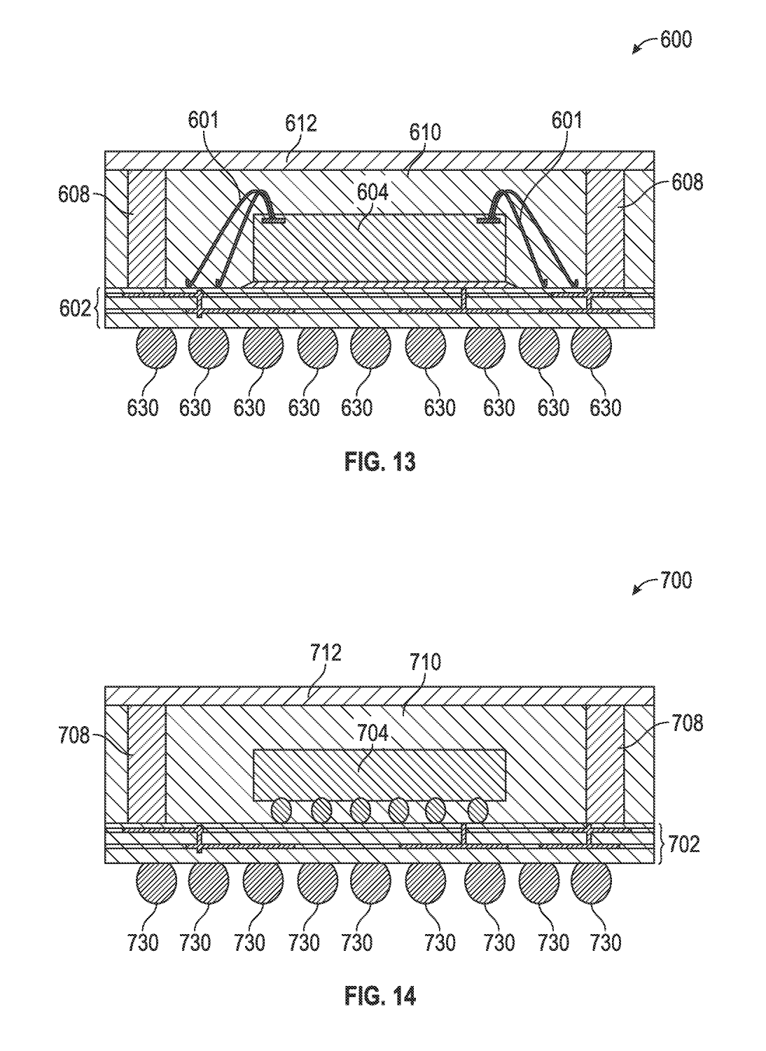

FIG. 14 depicts an alternative embodiment of a shielded semiconductor device package 700 that includes a flip chip electrical component 704, such as a flip chip semiconductor die or a no-leads semiconductor device package. As illustrated, the I/Os of the electrical component 704 may include or otherwise be coupled to solder bumps or the like that facilitate soldering, bonding, or otherwise mounting the electrical component 704 to the routing structure 702 in a manner that provides electrical connections between the I/Os of the electrical component 704 and the routing structure 702. In a similar manner as described above, the routing structure 702 is configured to electrically connect the I/Os of the electrical component 704 to the particular connection structures 730 corresponding to those I/Os of the electrical component 704. Likewise, the routing structure 702 provides an electrical connection between the ground reference voltage for the device package 700 and/or electrical component 704 and the frame structure 708 and/or shielding structure 712, and the molding compound 710 surrounds or otherwise encapsulates the electrical component 704 and the frame structure 708.

For the sake of brevity, conventional techniques related to semiconductor and/or integrated circuit fabrication, EMI shielding, and other functional aspects of the subject matter may not be described in detail herein. In addition, certain terminology may be used herein for the purpose of reference only, and thus are not intended to be limiting. For example, the terms “first,” “second,” and other such numerical terms referring to structures do not imply a sequence or order unless clearly indicated by the context, and terms such as “upper,” “lower,” “top,” “bottom,” and the like refer to directions in the drawings to which reference is made. The foregoing description also refers to elements or nodes or features being “connected” or “coupled” together. As used herein, unless expressly stated otherwise, “connected” means that one element is directly joined to (or directly communicates with) another element, and not necessarily mechanically. Likewise, unless expressly stated otherwise, “coupled” means that one element is directly or indirectly joined to (or directly or indirectly communicates with) another element, and not necessarily mechanically. Thus, although a schematic shown in the figures may depict direct electrical connections between circuit elements and/or terminals, alternative embodiments may employ intervening circuit elements and/or components while functioning in a substantially similar manner

In conclusion, systems, devices, and methods configured in accordance with example embodiments of the invention relate to:

An apparatus for a device package is provided. The device package comprises one or more electrical components, a molding compound overlying the one or more electrical components, a frame structure circumscribing the one or more electrical components, and a shielding structure overlying the frame structure and the one or more electrical components. The shielding structure contacts a first surface of the frame structure, at least a portion of the molding compound resides between the shielding structure and the one or more electrical components, and the first surface of the frame structure is aligned with a second surface of the portion of the molding compound. In one embodiment, the shielding structure is planar. In another embodiment, a planar surface of the shielding structure abuts the first surface and the second surface. In yet another embodiment, the second surface is planar, wherein the shielding structure contacts the second surface. In one or more embodiments, the shielding structure comprises a planar surface abutting the first surface and the second surface. In another embodiment, the shielding structure is bonded to the frame structure. In accordance with one or more embodiments, a second portion of the molding compound resides laterally between the frame structure and the one or more electrical components, and the frame structure resides laterally between the second portion of the molding compound and a third portion of the molding compound. In another embodiment, the device package further comprises a routing structure, wherein the one or more electrical components, the frame structure, and the molding compound overlie the routing structure. In some embodiments, the device package further comprises a connection structure to receive a reference voltage, wherein the routing structure provides an electrical connection between the connection structure and the frame structure.

In another exemplary embodiment, an apparatus for a device package comprises a routing structure, one or more electrical components overlying the routing structure, a molding compound overlying the routing structure and the one or more electrical components, and a frame structure overlying the routing structure and circumscribing the one or more electrical components. The molding compound has a planar upper surface and the frame structure has an upper surface aligned with the planar upper surface, wherein at least a first portion of the molding compound resides between the frame structure and the one or more electrical components and a second portion of the molding compound circumscribes the frame structure. The device package further comprises a shielding structure overlying the frame structure and the one or more electrical components, wherein the shielding structure contacts the upper surface of the frame structure and at least a third portion of the molding compound resides between the shielding structure and the one or more electrical components. In one embodiment, the device package further comprises a connection structure to receive a ground reference voltage, wherein the routing structure provides an electrical connection between the connection structure and the frame structure.

In another exemplary embodiment, a method of fabricating a device package is provided. The method comprises providing a frame structure circumscribing one or more electrical components, forming a molding compound overlying the one or more electrical components, and providing a shielding structure overlying the frame structure and the one or more electrical components. The frame structure has a first surface and the molding compound has a second surface aligned with the first surface. A first portion of the molding compound resides between the frame structure and the one or more electrical components, the shielding structure contacts the first surface of the frame structure, and a second portion of the molding compound resides between the one or more electrical components and the shielding structure. In one or more embodiments, forming the molding compound comprises forming the molding compound overlying the one or more electrical components and the frame structure and removing portions of the molding compound to obtain the second surface of the molding compound that is substantially aligned with the first surface of the frame structure. In one embodiment, removing portions of the molding compound comprises planarizing the molding compound to remove excess portions of the molding compound overlying the frame structure to expose the first surface. In another embodiment, removing portions of the molding compound comprises uniformly grinding the molding compound to a thickness that results in the first surface of the frame structure being exposed. In yet another embodiment, forming the molding compound comprises forming the molding compound overlying the one or more electrical components to a height of the frame structure. In one or more embodiments, providing the shielding structure comprises depositing a layer of a conductive material overlying the frame structure and the molding compound. In another embodiment, providing the shielding structure comprises bonding a conductive material to the frame structure. In yet another embodiment, the method further comprises forming a routing structure on the frame structure and the one or more electrical components and forming a connection interface for receiving a ground reference voltage on the routing structure, wherein the routing structure provides an electrical connection between the connection interface and the frame structure.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application. Accordingly, details of the exemplary embodiments or other limitations described above should not be read into the claims absent a clear intention to the contrary.

What is claimed is:

1. A device package comprising:
one or more electrical components;
a molding compound overlying the one or more electrical components;
a frame structure circumscribing the one or more electrical components; and
a shielding structure overlying the frame structure and the one or more electrical components, wherein:
the shielding structure contacts a first surface of the frame structure;
at least a portion of the molding compound resides between the shielding structure and the one or more electrical components; and
the first surface of the frame structure is aligned with a second surface of the portion of the molding compound.

2. The device package of claim 1, wherein the shielding structure is planar.

3. The device package of claim 1, wherein a planar surface of the shielding structure abuts the first surface and the second surface.

4. The device package of claim 1, wherein the second surface is planar.

5. The device package of claim 4, wherein the shielding structure contacts the second surface.

6. The device package of claim 5, wherein the shielding structure comprises a planar surface abutting the first surface and the second surface.

7. The device package of claim 1, wherein the shielding structure is bonded to the frame structure.

8. The device package of claim 1, wherein:
a second portion of the molding compound resides laterally between the frame structure and the one or more electrical components; and
the frame structure resides laterally between the second portion of the molding compound and a third portion of the molding compound.

9. The device package of claim 1, further comprising a routing structure, wherein the one or more electrical components, the frame structure, and the molding compound overlie the routing structure.

10. The device package of claim 9, further comprising a connection structure to receive a reference voltage, wherein the routing structure provides an electrical connection between the connection structure and the frame structure.

11. A device package comprising:
a routing structure;
one or more electrical components overlying the routing structure;
a molding compound overlying the routing structure and the one or more electrical components, the molding compound having a planar upper surface;
a frame structure overlying the routing structure and circumscribing the one or more electrical components, the frame structure having an upper surface aligned with the planar upper surface, wherein at least a first portion of the molding compound resides between the frame structure and the one or more electrical components and a second portion of the molding compound circumscribes the frame structure; and
a shielding structure overlying the frame structure and the one or more electrical components, wherein the shielding structure contacts the upper surface of the frame structure and at least a third portion of the molding compound resides between the shielding structure and the one or more electrical components.

12. The device package of claim 11, further comprising a connection structure to receive a ground reference voltage, wherein the routing structure provides an electrical connection between the connection structure and the frame structure.

13. A method of fabricating a device package, the method comprising:
providing a frame structure circumscribing one or more electrical components, the frame structure having a first surface;
forming a molding compound overlying the one or more electrical components, the molding compound having a second surface aligned with the first surface, wherein a first portion of the molding compound resides between the frame structure and the one or more electrical components; and
providing a shielding structure overlying the frame structure and the one or more electrical components, wherein the shielding structure contacts the first surface of the frame structure and a second portion of the molding compound resides between the one or more electrical components and the shielding structure.

14. The method of claim 13, wherein forming the molding compound comprises:
forming the molding compound overlying the one or more electrical components and the frame structure; and
removing portions of the molding compound to obtain the second surface of the molding compound that is substantially aligned with the first surface of the frame structure.

15. The method of claim 14, wherein removing portions of the molding compound comprises planarizing the molding compound to remove excess portions of the molding compound overlying the frame structure to expose the first surface.

16. The method of claim 14, wherein removing portions of the molding compound comprises uniformly grinding the molding compound to a thickness that results in the first surface of the frame structure being exposed.

17. The method of claim 13, wherein forming the molding compound comprises forming the molding compound overlying the one or more electrical components to a height of the frame structure.

18. The method of claim 13, wherein providing the shielding structure comprises depositing a layer of a conductive material overlying the frame structure and the molding compound.

19. The method of claim 13, wherein providing the shielding structure comprises bonding a conductive material to the frame structure.

20. The method of claim 13, further comprising:
forming a routing structure on the frame structure and the one or more electrical components; and
forming a connection interface for receiving a ground reference voltage on the routing structure, wherein the routing structure provides an electrical connection between the connection interface and the frame structure.
